(19) United States
(12) Patent Application Publication
(10) Pub. No.: US 2013/0110426 A1
(43) Pub. Date: May 2, 2013

(54) ENERGY METER INTERFACE SYSTEM AND METHOD

(71) Applicant: Terry Lee Van Olst, Coal Center, PA (US)

(72) Inventor: Terry Lee Van Olst, Coal Center, PA (US)

(73) Assignee: General Electric Company, Schenectady, NY (US)

(21) Appl. No.: 13/288,019

(22) Filed: Nov. 2, 2011

(51) Int. Cl. G01R 21/06

(52) U.S. Cl. 702/62

(57) ABSTRACT

Present embodiments include systems and methods for interfacing with an energy meter using a series of taps on an enclosure of the meter. For example, in one embodiment, an energy meter is provided that includes metering circuitry configured to monitor energy consumption, a processor configured to control the metering circuitry, an enclosure disposed over at least a portion of the metering circuitry and the processor, and an accelerometer communicatively coupled to the processor and configured to enable user interactions with the energy meter via tap sequences on the enclosure.

### BACKGROUND OF THE INVENTION

The subject matter disclosed herein relates to an energy consumption monitoring system configured to receive instructions from a user.

Energy meters incorporate many functionalities relating to energy consumption measurement and monitoring. One energy meter make or model may be deployed by many utility companies to consumers. Users of energy meters may include various utility companies, consumers, and technicians. Certain energy meters may include mechanical switches or plunger mechanisms to allow users to interface with the meters. However, a user may not have access to the equipment suitable for interfacing with the energy meter, as may be desirable to view and edit certain operational parameters, view information relating to power consumption, or to set customizable alerts. Accordingly, simple adjustments to the meter may be difficult and time consuming

### BRIEF DESCRIPTION OF THE INVENTION

Certain embodiments commensurate in scope with the originally claimed invention are summarized below. These embodiments are not intended to limit the scope of the claimed invention, but rather these embodiments are intended only to provide a brief summary of possible forms of the invention. Indeed, the invention may encompass a variety of forms that may be similar to or different from the embodiments set forth below.

In one embodiment, a utility meter is provided that includes metering circuitry configured to monitor consumption of a utility, a processor configured to control the metering circuitry, an enclosure disposed over at least a portion of the metering circuitry and the processor, and an accelerometer communicatively coupled to the processor. The accelerometer is configured to enable user interactions with the energy meter via one or more taps on the enclosure.

In another embodiment, an energy meter system is provided. The system includes user interface circuitry having an accelerometer circuit configured to measure acceleration, and a communications device coupled to the accelerometer and having a first interface configured to communicatively couple the user interface circuitry with a second interface of an energy meter, the energy meter having metering circuitry configured to monitor energy consumption. The user interface circuitry is configured to enable user interactions with the energy meter using measured acceleration resulting from taps by a user on an enclosure of the energy meter.

In a further embodiment, a method is provided. The method includes monitoring energy consumption of a load using metering circuitry of the energy meter, controlling an operational parameter of the metering circuitry using a processor, measuring acceleration resulting from a tap sequence on an enclosure of the energy meter using an accelerometer, and adjusting the operational parameter based on the measured acceleration.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a block diagram of an embodiment of an electrical system in which tap interface-enabled energy meters may monitor power consumption by various loads;

FIG. 2 is a block diagram of an embodiment of the tap interface-enabled energy meter of FIG. 1;

FIG. 3 is a block diagram of an embodiment of the tap interface-enabled energy meter of FIG. 1;

FIG. 4 is a schematic illustration of side taps that may be used to interface with the energy meter of FIGS. 2 and 3;

FIG. 5 is a schematic illustration of front taps that may be used to interface with the energy meter of FIGS. 2 and 3;

FIG. 6 is a process flow diagram illustrating an embodiment of a method of operation of the tap interface-enabled energy meter of FIGS. 2 and 3; and

FIG. 7 is a schematic illustration of an embodiment of a display of the tap interface-enabled energy meter of FIGS. 2 and 3.

### DETAILED DESCRIPTION OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements.

The disclosed embodiments relate to meters, such as energy meters, gas meters, heat meters, water meters, or any such utility meter, having one or more accelerometers to enable a user to interface with the energy meter using a pattern or series of taps on the energy meter. Thus, the energy meters of the disclosed embodiments may be considered to be tap interface-enabled energy meters. It should be noted that while the disclosed embodiments are presented in the context of a tap interface for energy meters, i.e., meters used to monitor/control electricity consumption, that the embodiments disclosed herein are also applicable to any utility meter, such as gas meters, heat meters and water meters. Accordingly, tap interface-enabled utility meters, such as tap interface-enabled gas meters tap interface-enabled heat meters and tap interface-enabled water meters, are also presently contemplated. Tap sequences, as discussed herein, may include one or more taps on the meter, where the sequence may be determined based on a location, direction, magnitude of force, length of tap (i.e., prolonged pressing), or any combination thereof, of each tap, and/or a frequency (e.g., slow or rapid), timing, or a combination, of a plurality of taps in a given time.

Generally, the one or more accelerometers of the tap interface-enabled energy meter may detect/measure the acceleration resulting from the taps on the energy meter. The one or more accelerometers may also be used to detect/measure other vibration-inducing events, such as seismic events, tampering, weather events, or other situations that may affect power consumption and availability. The taps may be on the enclosure of the energy meter, or on a separate module attached to the energy meter. The one or more accelerometers may detect and, in some embodiments, determine, various aspects of the taps, such as the direction in which the taps are applied, the force generated by the taps, the location of the taps, or any combination thereof, to ascertain a given sequence of the taps, i.e., tap sequences. To enable the user to interact with the energy meter using the tap sequences, the energy meter may be suitably configured to respond to the tap sequences, as discussed in detail below. For example, the energy meter may include firmware configured to control the operation of various metering circuitry in response to certain tap sequences. The energy meter may also include a digital display, such as a liquid crystal display (LCD), that is configured or configurable to display information relating to vibrations or taps experienced by the energy meter. The display may also enable a user to view various settings, select various operational modes or states of the energy meter, and so on.

Tap interface-enabled energy meters may reduce the cost associated with energy meters, such as costs associated with servicing and maintenance, by enabling a user interface without the use of specific tools or electronic hardware. As a non-limiting example, a technician may utilize a series of prescribed tap sequences to access, for example, administrator-level settings of the meter. Thus, using specific tap sequences, the technician may perform servicing and diagnostics, change various settings of the meter, enable energy service to a given location, or similar operations. Tap interface-enabled energy meters may also enable enhanced consumer interface with the energy meter. For example, consumers may access user-level settings of the energy meter to view energy usage, set alarms, request diagnostics/servicing, and so on. Accordingly, the tap interface-enabled energy meters according to present embodiments may reduce the amount of equipment and other devices typically used to access and interface with energy meters, such as push buttons and associated drivers, plunger mechanisms, or other costly components. Furthermore, enhanced consumer interfacing with the energy meter may encourage responsible energy usage, as a consumer is able to readily view substantially real-time information related to energy consumption, thus having a positive impact on the environment and possibly reducing energy consumption during peak times. Additionally, the absence or substantial reduction of mechanical devices interfacing with but external to the main meter assembly (MMA) of the energy meter may serve to enable a better seal of the energy meter so as to provide enhanced protection of the meter from weather and the elements.

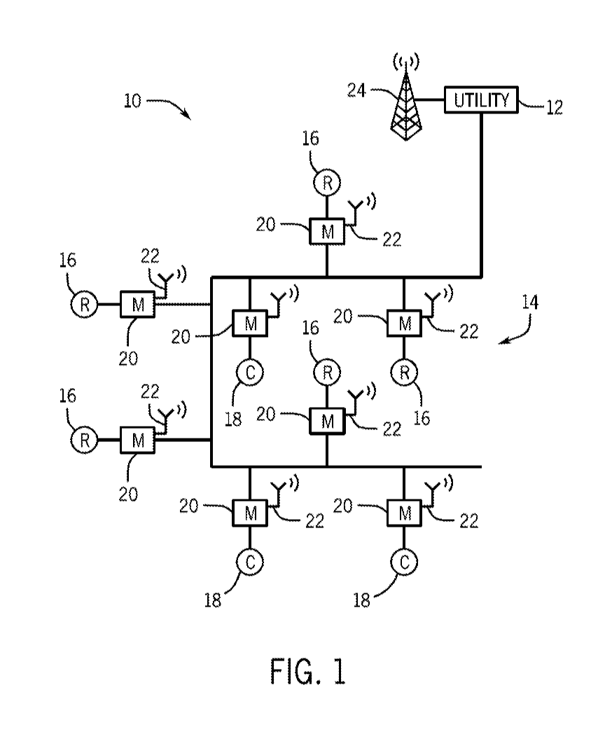

With the foregoing in mind, FIG. 1 represents a block diagram of an electrical system 10, which includes a power utility 12 (i.e., a utility provider) that supplies power to a power grid 14. Loads on the power grid may include, for example, residential establishments 16 and commercial establishments 18. Tap interface-enabled energy meters 20 in accordance with present embodiments may monitor the power consumption of the residential establishments 16 or commercial establishments 18. As mentioned above and described in greater detail below, the tap interface-enabled energy meters 20 may enable a technician, consumer, or other user to interface with the energy meters 20 using a series of taps, rather than dedicated input devices such as push buttons and plungers.

The tap interface-enabled energy meters 20 may monitor power consumed by the residential establishment 16 or the commercial establishment 18 to which it is affixed. Additionally, the tap interface-enabled energy meters 20 may communicate with the power utility 12 via data communication links 22. Such data communication links 22 may be wired (e.g., over wired telecommunication infrastructure) or wireless (e.g., RF Mesh communications, a cellular network or other wireless broadband such as WiMax). Similarly, the power utility 12 may employ a communication link 24 to communicate with the various tap interface-enabled energy meters 20. The communication link 24 may be wired or wireless to communicate to the various communication links 22 of the tap interface-enabled energy meters 20. The tap interface-enabled energy meters 20 may obtain consumer account balance information, dynamic power prices (e.g., real-time pricing of electricity), and/or indications of abnormal activity on the power grid 14 (e.g., rapid spikes in demand) via the communication links 22 to the communication link 24 of the power utility 12. A utility or consumer may view this information by prompting the energy meter 20 using a series of tap sequences, and may configure the energy meter 20 based on other tap sequences. For example, a consumer may configure the energy meter 20 to provide certain alerts based on the monitored power consumption and the information obtained via communication with the power utility 12.

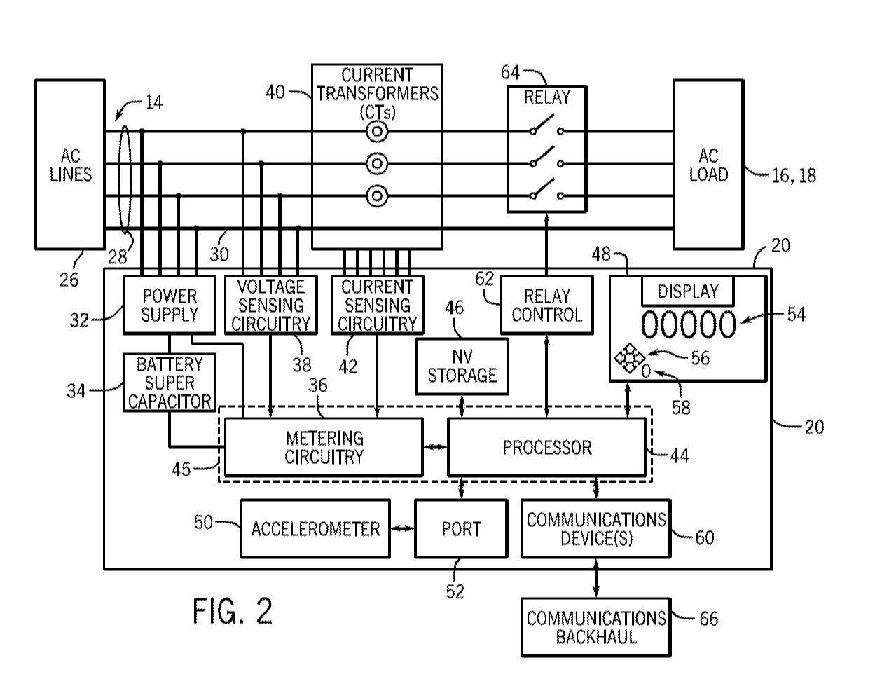

The tap interface-enabled energy meters 20 may take a variety of forms. One embodiment of a three-phase tap interface-enabled energy meter 20 is illustrated in FIG. 2 as joined to the power grid 14, as power flows from AC lines 26 to an AC load 16, 18 (e.g., one or more of the residential establishments 16 and/or the commercial establishments 18). Although the embodiment of FIG. 2 involves monitoring three-phase power, alternative embodiments of the tap interface-enabled energy meter 20 may monitor single-phase power. In the illustrated embodiment, the AC lines 26 may transmit three-phase power via three phase lines 28 and a neutral line 30. The tap interface-enabled energy meter 20 may obtain power via power supply circuitry 32 that may couple to the three phase lines 28 and the neutral line 30 for its internal power consumption. To backup power consumption data in the event of a power outage, the power supply circuitry 32 may also charge a battery and/or super capacitor 34. In alternative embodiments, the backup power may be fed by a non-rechargeable battery.

Metering circuitry 36 may ascertain power consumption by monitoring the voltage and current traversing the AC lines 26 to the AC load 16, 18. In particular, voltage sensing circuitry 38 may determine the voltage based on the three phase lines 28 and the neutral line 30. Current transformers (CTs) 40 and current sensing circuitry 42 may determine the current flowing through the three phase lines 28. The metering circuitry 36 may output the current power consumption values to a processor 44. The metering circuitry 36 may sense the voltage and current inputs and send corresponding signals to the processor 44, which calculates the energy accumulation, power factor, active power, reactive power and maximum demand, etc. The processor 44 may store the demand details in nonvolatile storage 46, which may be NVRAM (EEPROM, flash, or any other non-volatile storage). In certain embodiments, multiple functions of the tap interface-enabled energy meter 20 may be implemented in a single chip solution, in which a single chip will perform both the voltage/current sensing and the calculation of demand parameters. From the demand data in the processor 44 (which would be the main chip in case of single ship solution), the processor 44 will generate data to be displayed on display 48, which may also be configured to display usage information, as well as tap sequence information, as discussed below. The nature of the indications provided on the display 48 may be based entirely or in part on user-configured settings.

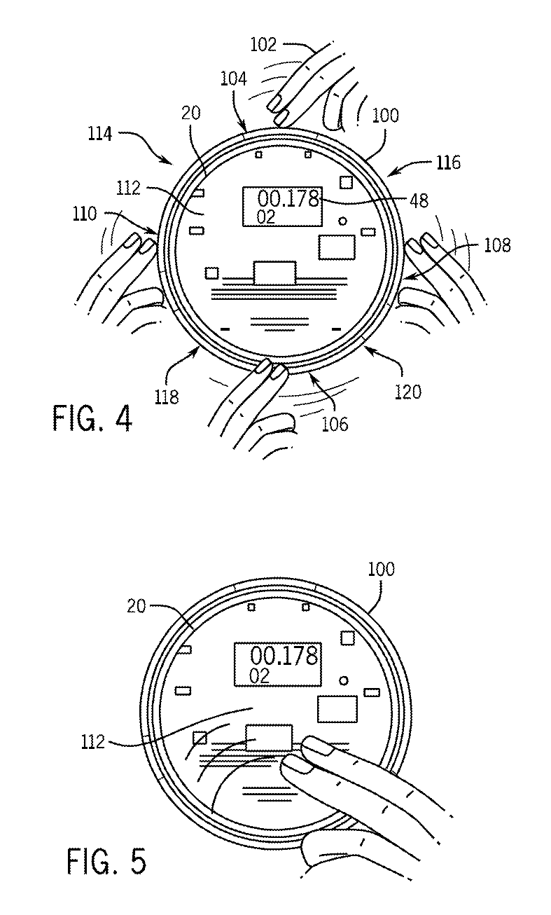

The processor 44 may include one or more microprocessors, such as one or more “general-purpose” microprocessors, one or more application-specific processors (ASICs), a field-programmable array, or a combination of such processing components, which may control the general operation of the tap interface-enabled energy meter 20 in response to acceleration detected by an accelerometer 50. For example, as discussed below, the acceleration detected by the accelerometer 50 may be caused by taps on an enclosure (FIGS. 4 and 5) of the energy meter by a user, vibration from weather or seismic events, tampering, or any combination thereof

The actions associated with how the meter 20 responds to taps by the user and/or vibrations (e.g., vibrations associated with seismic and/or weather activity) may be totally or partially configurable by the user during the configuration and setup of the meter 20. In some embodiments, a base configuration may be applied to the meter 20, and made common for the entire meter population for the utility 12 by appropriate configuration of the metering circuitry 36 and/or the processor 44. Further, while the illustrated embodiment depicts the metering circuitry 36 and the processor 44 as being separate components, as noted above they may be integrated into a single device or chip having one or more processors configured to control the metering components (e.g., the voltage and current sensing circuitry 38, 42) and perform routines in response to detected/measured acceleration. Thus, the processor 44, the metering circuitry 36 and the processor 44, or a single device performing the presently disclosed functions of the metering circuitry 36 and the processor 44, may be considered to be a microcontroller 45 of the energy meter 20.

The processor 44 may include one or more instruction set processors (e.g., RISC) and/or other related chipsets. Nonvolatile storage 46 may store the current and/or certain historical power consumption values, as well as provide instructions, such as on firmware, to enable the processor 44 to respond to detected acceleration. In addition, the nonvolatile storage 46 may be utilized for persistent storage of data and/or instructions. The nonvolatile storage 46 may include flash memory, a hard drive, or any other optical, magnetic, and/or solid-state storage media. By way of example, the nonvolatile storage 46 may be used to store data files, such as historical power consumption as determined by the metering circuitry 36, as well as indications of consumer account balance information, dynamic power prices, and/or abnormal activity on the power grid 14 as communicated to the tap interface-enabled energy meter 20 by the power utility 12. For example, in certain embodiments, the nonvolatile storage 46 may store average and maximum rates of power consumption per hour, day, week, and/or month. In accordance with present embodiments, the nonvolatile storage 46 may store configuration data related to detected acceleration, such as user-defined actions based on specific tap sequences or vibrational events. For example, the NV storage 46 may store a set of instructions to be performed by the processor 44 in response to certain predefined tap sequences, or in response to detecting potential seismic or weather activity.

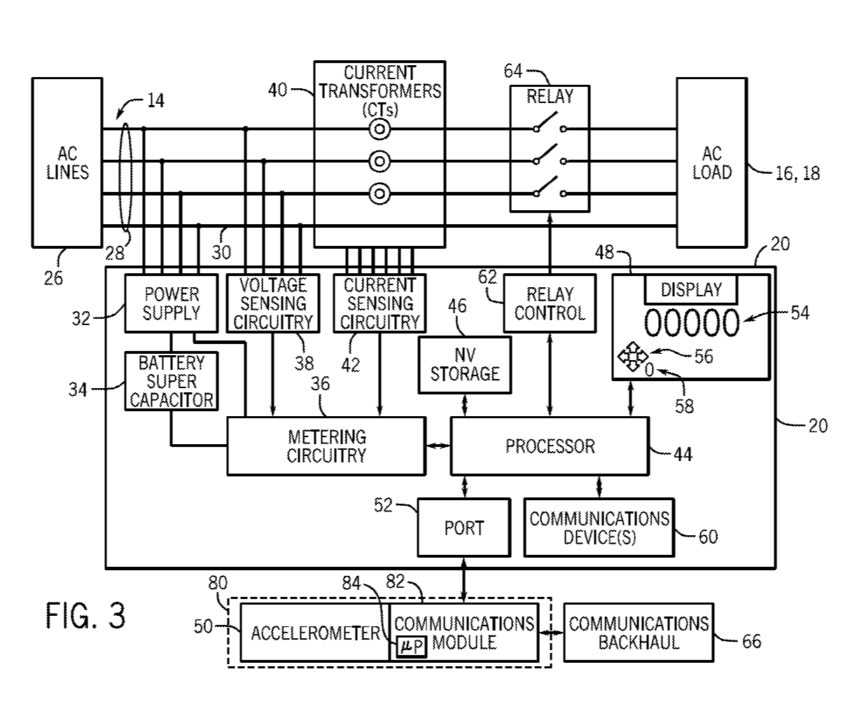

To provide the acceleration-related data to the processor 44, the accelerometer 50 may be directly or indirectly communicatively coupled to the processor 44. For example, in FIG. 2, the accelerometer 50 is coupled to a port 52 (e.g., an input/output or I/P pin or pin set) of the processor 44 (i.e., directly communicatively coupled). In the illustrated embodiment, the processor 44 is configured to sample acceleration-related information of the accelerometer 50 (i.e., acceleration-related information stored in a register or other region of the accelerometer 50) and/or to receive acceleration-related data (e.g., analog or digital) or instructions from the accelerometer 50. The processor 44 may process this data to determine specific actions to be taken to control elements of the energy meter 20. Alternatively, as discussed with respect to FIG. 3, the accelerometer 50 may be indirectly communicatively coupled to the processor 44 via one or more communications modules or devices, such as one or more advanced metering infrastructure (AMI) communications modules.

In one non-limiting example of the operation of the tap interface-enabled energy meter 20 of FIG. 2, the accelerometer 50 may be connected to an I/O pin or pin set (port 52) of the processor 44 which can change state, in which the processor 44 may poll the status of the I/O pin, or respond based on an interrupt that may be generated as a result of a state change on the I/O pin. When the processor 44 recognizes a change in status, firmware logic of the meter 20 (e.g., on the NV storage 46, the memory circuitry 36, the processor 44, or any combination thereof) may provide instructions to read the status of the accelerometer 50 to determine the status of the accelerometer 50 and action to be taken as a result of the status.

Thus, the accelerometer 50 may be a passive sensor that is sampled at intervals or substantially continuously by the processor 44, or may be a more active component having a processor and associated firmware for performing acceleration detecting and related processing. For example, the accelerometer 50 may include at least an accelerometer circuit, such as a solid-state microelecromechanical systems (MEMS) device to generate acceleration-related signals. The accelerometer 50 may also include, as noted, one or more processors for processing the signals representative of the acceleration to generate digital data for the processor 44, instructions for the processor 44, updates for various elements of the meter 20 (e.g., updates for the display 48), or any such data or instructions relating to detected/measured acceleration.

In one non-limiting example, depending on the configuration and status of the accelerometer 50, the meter 20 may enter into a mode to modify memory and/or update a status of the display 48. This may provide a local interface in which an individual (e.g., a consumer, a technician) tapping on the front, top, bottom, or sides of the meter 20 can control the information displayed on the display 48. For example, in FIG. 2, the display 48 provides a series of user-viewable indications such as text 54, which may list various operational modes of the meter 20, configuration menus, the status of the meter 20 (i.e., the state or operational mode of the meter 20), the power consumption by the consumer, error messages, and similar text indicia.

The illustrated display 48 also includes a four-way arrow indicator 56, which includes a series of arrows pointing up, down, left, and right. In certain embodiments, as a user taps on the energy meter 20, the arrow corresponding to the location at which the meter 20 was tapped by the user may illuminate, bold, flash, change color, or provide a similar visual indication. In one non-limiting example, as a user taps the left side of the meter 20, the left arrow may become brighter than the other arrows. Additionally, a number indicator 58 may display the number of times a particular side has been tapped. In the example above, as the user taps the left side of the energy meter 20, the number indicator 58 may display an alphanumeric character, such as “1,” “one,” or a similar indication. As the user proceeds to tap the left side of the meter 20 an additional number of times, the number indicator 58 may increment, such that tapping the left side 5 times in succession results in the number indicator displaying “5,” “five,” or the like. Similar indications may be provided for all arrows, wherein each arrow may have a dedicated number indicator, or there may be the single number indicator 58 which returns to “0” or “1” upon tapping a different location of the meter 20. In another non-limiting example, as the user initially taps the left side, such as twice, the left arrow may brighten or blink while the number indicator 58 indicates a value of “2.” The user may then tap the top of the energy meter 20, in which case the up arrow may illuminate or blink, and the number indicator 58 may return to a value of “1.” Initially, before any taps on the meter 20, or during events that cause excessive vibration, the number indicator 58 may display “0.” In situations where the user taps on the front of the energy meter 20, all of the arrows of the four-way arrow indicator 56 may blink, flash, or illuminate. In situations where the user taps on a top right side of the energy meter 20, the up and right arrows may illuminate, brighten, or flash, or any combination thereof. Similar indications may be provided for top left taps, bottom left taps, and bottom right taps, wherein the up and left arrows, the down and left arrows, and the down and right arrows, respectively, may illuminate, brighten, or flash, or any combination thereof

As mentioned above, the tap interface-enabled energy meter 20 may communicate with the power utility 12 to obtain displayable indications of consumer account balance information, dynamic power prices, and/or abnormal activity on the power grid 14. Such communication may take place via one or more communication devices 60, which may include interfaces for a personal area network (PAN), such as a Bluetooth network, a local area network (LAN) such as an 802.11x Wi-Fi network, a wide area network (WAN) such as a 3G, 4G, or any such cellular network (e.g., WiMax), an infrared (IR) communication link, a Universal Serial Bus (USB) port, and/or a power line data transmission network such as Power Line Communication (PLC) or Power Line Carrier Communication (PLCC). In accordance with certain embodiments, the communications devices 60 include one or more advanced metering infrastructure/automated meter reading (AMI/AMR) communications modules.

The AMI/AMR communications modules provide remote communications to the power utility 12 to provide meter status information, such as meter readings, status information and other diagnostic information such as alarms, errors or warnings. The AMI/AMR communications module can also be used for remote on demand queries for meter-specific data, as well as to provide an interface by which the firmware of the meter 20 or other peripheral devices can be configured or remotely updated with new firmware or configuration data. The communications devices 60 may, additionally or alternatively, include a local communications interface, such as an optical communications module and/or a local RS-232/RS-485 communications module. Through such interfaces, the meter can be queried, configured and updated in a similar fashion as with the AMI/AMR communications module, but through a local direct connection with a local interface device (computer, personal data assistant (PDA), smart phone, keyboard, touch pad, joystick, etc.) directly attached to the meter 20.

In certain embodiments, the power utility 12 may communicate with the tap interface-enabled energy meter 20 to remotely control the flow of power to the AC load 16, 18. Based on instructions from the power utility 12 via the communication device(s) 60, the processor 44 may correspondingly instruct relay control circuitry 62 to open or close a relay 64. For example, if the consumer has not paid for the power being received, the relay 64 may be opened, disconnecting the AC load 16, 18 from the AC lines 26. Once the consumer has paid for further electrical power, the power utility 12 may instruct the tap interface-enabled energy meter 20 to close the relay 64, reconnecting power to the AC load 16, 18. Alternatively, the power utility 12 may instruct the tap interface-enabled energy meter 20 to “arm” the relay 64, such that the meter 20 prompts the consumer via the display 48 to input a prescribed tap sequence to re-initiate power to the load 16, 18 by closing the relay 64. Indeed, in certain situations, such as when a customer is moving into a residence, the power utility 12 may arm the relay 64, and the consumer may be notified that the power to the residence may be initiated upon tap-based interaction with the tap interface-enabled energy meter 20.

In certain embodiments, the accelerometer 50 may also provide a status to the meter 20 to communicate with a remote computer, cellular phone, or a similar device. In such embodiments, the processor 44 may enter into a firmware routine that establishes a communications session with any one or a combination of the communications device(s) 60 (e.g., the AMI/AMR communications module) to connect with a remote computer, which may be located at a utility or a mobile communications device (e.g., a mobile phone) or over a communications backhaul 66, and provide substantially real-time diagnostic status information to the remotely connected device. Communications over the backhaul 66 may include GSM/GPRS cellular, Power Line Carrier (PLC), RF Mesh, Ethernet, RS-232, RS-485 and other communications modes, which enable communications with another device either locally or remotely connected to the meter 20. In one non-limiting example, the accelerometer 50 may direct the meter 20 to communicate with a consumer's cellular telephone, such as via an automated call, an e-mail, a text message, or the like, to inform the consumer that a technician or other user is interfacing with or has interfaced with the meter 20, that the power to the residence or commercial establishment is down or is likely to drop due to weather or seismic conditions, and so on. Thus, depending on the configuration of the meter 20 and the state (i.e., operational mode) of the meter 20, the meter 20 is able to respond based on a set of predefined instructions for the type of vibration or forces applied to the meter 20 and detected/sensed by the accelerometer 50. Such actions can include, but are not limited to, updates to the local display 48, updates to the NV memory 46, or establishing communications over the backhaul communications network to a remote computer or other device.

As noted, the behavior of the meter 20 associated with the acceleration detected by the accelerometer 50 may be totally or partially configurable by a user and/or at the location of manufacture by providing appropriate firmware and software to enable configuration, and also to provide a base configuration on which to operate. For example, to enable the meter 20 to monitor seismic activity, the meter 20 may be set to a learn mode when first installed. When in the learn mode, the meter 20 may monitor all vibration and forces to characterize the typical vibrations associated with the location in which the meter 20 is installed to avoid potential false positives (i.e. taking action that there might be seismic activity, in the case where the vibration may be associated with a truck or train passing by a building causing prolonged vibration). The learn mode could be configurable by the user to be a matter of hours, days or indefinitely. Indeed, the longer the meter 20 and associated accelerometer 50 are able to analyze the characteristics of the environment, the more accurate the meter 20 may become in differentiating various forces and the actions to take based on the characteristics of the forces applied.

The tap interface-enabled energy meter 20 may also be configured to respond to a potential tamper, which may be characterized by excessive forces being applied to the meter 20 if the meter 20 is being removed or rotated. The logic stored in the meter 20 (e.g., in the NV storage 46 or the processor 44) would instruct the communications device(s) 60 (e.g., the AMI/AMR communications module) to send a tamper alarm to a remote computer (e.g., to a utility back office software), to notify the utility 12 of a potential tamper situation. In such a situation, the communications device(s) 60 may be powered for a time that is sufficient to provide a message to the utility 12 over the communications backhaul 66. The meter 20 may also register a tamper alarm in the NV storage 46 of the meter 20 with a date/time stamp, when the tamper has occurred.

As noted above, the accelerometer 50 can be directly or indirectly communicatively coupled to the processor 44. Accordingly, while FIG. 2 depicts an embodiment where the accelerometer 50 is directly communicatively coupled to the processor 44, FIG. 3 depicts an embodiment of the tap interface-enabled energy meter 20 having the accelerometer 50 indirectly coupled with the processor 44. Specifically, in FIG. 3, the accelerometer 50 is a part of a daughter board 80 (e.g., a printed circuit board) that is coupled to the energy meter 20. The daughter board 80 includes at least one communications module 82 that is configured to enable communication between the accelerometer 50 and the processor 44. Thus, the daughter board 80 may be configured to retrofit an energy meter to enable tap interface functionality with the existing energy meter hardware, as discussed below. Indeed, the daughter board 80 may be provided as all or part of an add-on feature to the energy meter 20, such as via a chip set, a track pad, a touch pad, a joystick, and the like, that has an accelerometer capable of measuring acceleration, tilt, forces, etc., to act as an input device.

While the communications module 82 may be any module that enables the transmission of information (e.g., wired or wireless) between the accelerometer 50 and the processor 44 of the energy meter 20, in certain embodiments, the communications module 82 is an AMI/AMR communications module. Thus, the communications module 82 may be externally connected to the meter 20 through the port 52 of the meter 20, which may include one or more AMI or local RS-232/RS-485 communications ports. Such a configuration may enable legacy meters to have a similar functionality of the meter 20 of FIG. 2.

The communications module 82 of the daughter board 80, in addition to enabling communication between the accelerometer 50 and the processor 44, includes a microprocessor 84 that is configured to provide for all logic and actions associated with the accelerometer 50. Thus, the accelerometer 50 may cause similar actions to be performed by the energy meter 20 as described above with respect to FIG. 2. In certain embodiments, the communications module 82 is configured to provide status update information to the meter 20 (e.g., the processor 44) to enable the meter 20 to log events and/or alarm information. However, in certain embodiments, such updates may not be performed, and the communications module 82 may have the logic to control certain operational parameters of the meter 20 based on vibration, tapping activities and other forces applied to the meter 20.

The communications module 82 may also provide instructions to the meter 20 for updating the display 48. For example, the communications module 82 may provide direct updates to the meter registers via an AMI communications port, wherein the updates enable indications on the display when tapping activity occurs on the meter 20. For example, the display 48 may indicate the location of the taps, the tap count, the relative force of the taps, and other activity, such as abnormal vibrational forces (e.g., from seismic or weather activity). Additionally or alternatively, the communications module 82 may include a status display (e.g., an LCD or LED display) for providing viewable indications relating to forces detected by the accelerometer 50.

Again, the accelerometer 50, which may be tied to a main meter assembly (MMA) of the meter 20, or may be indirectly communicatively coupled with the meter 20 using the communications module 82, is configured to enable the meter 20 to respond to taps at various locations on an enclosure 100 of the meter 20, as illustrated in FIGS. 4 and 5. As shown in FIG. 4, the meter 20 can be tapped by a user's hand 102 either on a top 104, bottom 106, right 108 or left 110 of the enclosure 100. As shown in FIG. 5, the user may also tap on a front cover 112 of the meter 20. In certain embodiments, the accelerometer 50 may also enable the meter 20 to respond to taps at a top left 114, top right 116, bottom left 118, and bottom right 120 location on the enclosure 100.

The meter 20, such as the processor 44 of the meter 20, may analyze the response from the accelerometer 50 as a result of the taps and determine a location and force of the tap. While the user may tap on the meter 20 using a hand, other devices or tools may be used that enable the accelerometer 50 to recognize a force being applied to the meter 20. As noted above, in embodiments where a valid tap or tap sequence is recognized, the meter 20 will perform certain predefined routines, such as logging, storing data, changing a state of the display 48, or causing the meter 20 to take some action such as notifying a remote office or local HAN (Home Area Network) device. Tapping sequences can include single, double or triple tapping sequences and a variety of tapping sequences in which the location where the tap occurs may vary from font, top, bottom right or left.

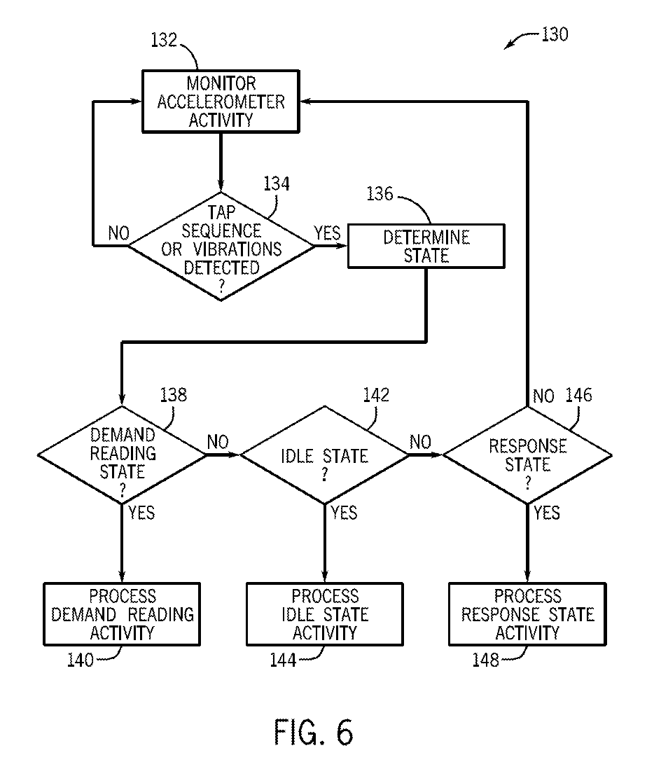

As noted above, while in operation, the accelerometer 50 of the tap interface-enabled energy meter 20 may passively sense acceleration resulting from forces applied to the meter 20. Depending on the nature of the acceleration, the meter 20 may perform certain tasks, such as by entering into certain operational modes, logging the acceleration event, communicating with a remote device, or any combination thereof. One embodiment of the manner in which the meter 20 may operate is illustrated as a process flow diagram in FIG. 6.

Specifically, FIG. 6 illustrates an embodiment of a method 130 of operation of the meter 20. The method 130 may be performed, in a general sense, by elements of the meter 20 including, but not limited to, the features discussed above with respect to FIGS. 2 and 3, such as the processor 44, the metering circuitry 36, the display 48, relay control 62, etc. Moreover, certain acts including adjusting operational parameters of the meter 20, updating displayed information, and the like, may be implemented by performing routines based on instructions stored on firmware, software, or a combination, where the firmware and/or software may be present on the processor 44, the metering circuitry 36, the NV storage 46, or any such area of the meter 20 capable of storing information such as code containing routines. Accordingly, the method 130 may be carried out, at least in part, based on code stored on a non-transitory machine-readable medium communicatively coupled to (e.g., directly or indirectly connected to) the meter 20.

The method 130 includes monitoring accelerometer activity (block 132). As discussed above with respect to FIGS. 2 and 3, acceleration resulting from tapping, vibration, or other forces, is detected by the accelerometer 50. The accelerometer 50 may provide data relating to the acceleration to the meter 20 (e.g., to the processor 44), or the meter 20 (e.g., the processor 40) may sample the state of the accelerometer 50 substantially continuously or at intervals to detect acceleration. In either case, the meter 20 may determine whether tap sequences or vibrations that call for the meter 20 to perform an action are detected (query 134).

In embodiments where no tap sequences or specific type of vibration is detected, the method 130 may cycle back to monitoring in accordance with block 132. However, in embodiments where the meter 20 detects tap sequences/vibrations, the method 130 progresses to a state determination (block 136). For example, the meter 20 may be set to a certain state before or during monitoring in accordance with block 132, such that a series of predefined actions may be performed in response to certain tapping actions or certain types of vibrations, such as vibrations associated with seismic or weather activity. In the illustrated embodiment, for example, the states may include, but are not limited to, a demand reading state, an idle state, and a response state, which are discussed below. In one embodiment, by way of example, the processor 44 may sample information stored in one or more areas of the NV storage 46, such as a value stored in a register, to determine the state of the meter 20 and perform at least some of the actions associated with the state.

In certain embodiments, the meter 20 may determine whether the meter 20 is in a demand reading state (query 138). When in the demand reading state, demand reading activity is processed (block 140). In the demand reading state, the tap interface-enabled meter 20 is being read by a user through the use of, for example, an optical port or manually by reading the display 48 on the meter 20 to determine real-time energy usage, historical usage, etc. If the meter 20 is read via an optical port, the meter 20 can enter a clear demand confirmation state, in which the user may tap the meter 20 to confirm that meter demand register (or other area storing demand information) can be cleared or reset to begin incrementing energy demand from zero.

In embodiments where the meter 20 is read manually (visually), the user can tap the meter 20 in a pre-defined sequence which is set either from the factory when the meter 20 is produced or pre-configured during installation by the utility to place the meter 20 in a command response state in which the user is able to enter commands, such as clear, delete, and display commands. The meter 20 may then determine whether to clear the demand register. The user may then respond by tapping the meter 20 in the appropriate sequence to reset the demand register. Once confirmed that the user wishes to reset the demand register, the meter demand register will be cleared or reset to begin incrementing energy demand from zero.

When resetting the demand register, there may be a specific tapping sequence that the user may need to enter before the confirmation to clear the demand register is complete. A tapping sequence could include, but is not limited to, delay between taps, multiple taps (e.g., double taps), location of the tap (top, bottom, left and right) and force applied when the tap is made. This may be configured by the utility as a security measure to ensure the meter 20 cannot arbitrarily enter a clear register state.

In embodiments where the meter 20 is not in a demand reading state, the method 130 then progresses to determining whether the meter 20 is in an idle state (query 142). In embodiments where the meter 20 is in an idle state, the method 130 progresses to processing idle state activity (block 144). In the idle state, a user can enter a register scrolling state through a pre-set tap sequence. When the meter 20 enters a register scrolling state, the meter 20 may enable the user to tap the meter 20 on the top, bottom, right or left, or any combination thereof, which may be recognized by the meter 20. In response to this tapping, the meter 20 will scroll through the display parameters. For example, the meter 20 may be in a register scroll state, and the user may tap the top of the meter 20 to advance to display 48 to the next display register in the scroll list. Thus, each time the top of the meter 20 is tapped, the next new register will be displayed. Conversely, if the bottom of the meter 20 is tapped, the contents of the previous register in the allowable register scroll list may be displayed. Left or right tapping may cause the meter 20 to advance through the scroll list in a pre-set forward and reverse sequence. In certain embodiments, the meter 20 may be in a time scroll sequence in which the user is able to tap the meter 20 in a sequence to change a speed (automatic scroll delay time) at which each register is automatically displayed. Also, in embodiments where the meter 20 is in an automatic display sequence, the automated meter scrolling could be paused by a tap on the front of the meter 20 or a pre-determined location of the enclosure 100.

In accordance with present embodiments, the accelerometer 50 analyzes the vibrations and forces being applied to the meter 20. In certain situations, the meter 20 may recognize specific forces/vibrations (i.e., a signature) that could indicate the meter 20 is being tampered with, or removed based on the force/vibration signature. When such vibrations or forces are recognized, the accelerometer 50 will be recognized by the processor 44, and act accordingly by logging the event that the meter 20 has been or is being tampered with, and may store the type of activity with a date time stamp into the NV storage 46 or other memory. Additionally, in embodiments where the meter 20 is a smart meter with communications capabilities, the meter 20 may communicate back to a central computer or computer system of the utility 12 through the use of the communications device(s) 60 to notify a remote user and/or a HAN (Home Area Network) device of such an event or activity on the meter 20.

In embodiments where the meter 20 is not in the idle state, the method 130 progresses to a determination as to whether the meter 20 is in a response state (query 146). In embodiments where the meter 20 is in a response state, the meter 20 processes response state activity (block 148). In the response state, the meter 20 is waiting for a response by the user to tap a desired sequence. For example, the utility 12, through the use of the communications devices 60, may place the meter into a response state remotely, which may call for the home owner or customer to tap on the meter 20 to enable the meter 20 to take a desired action. Such an action could be an arm/enable service in which the meter 20 waits for a tap response from the user/customer to enable service (e.g., to close the relay 66). Other actions include, but are not limited to, confirmation to time of use (TOU) or critical peak pricing updates. The meter 20 may be in the state for a set period of time before timing out.

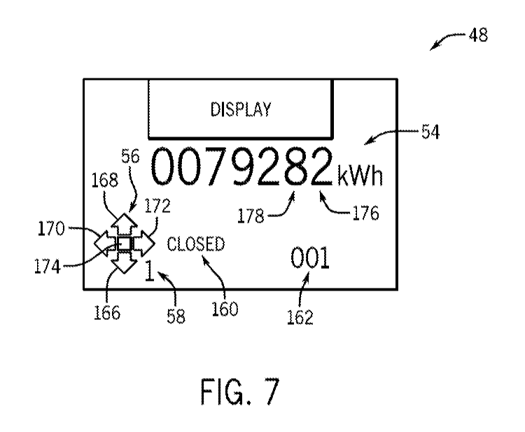

The user may also perform edits in the response state. For example, while in a response edit state, the user may tap the meter 20, causing a cursor on the display 48 to move left or right from character to character (e.g., in the text 54). The user may tap the top 104 or the bottom 106 to change the value of a displayed item. For example, tapping the top 104 could cause the value of a number/character to change from “1” to a “2” or “3,” depending on the number of taps at the top 104 of the enclosure 100. In a non-limiting example, tapping at the top 104 and bottom 106 of the enclosure 100 may enable scrolling through numeric, alpha and special character lists that are available for selection by tapping on the front 112. A non-limiting embodiment of the display 48 is provided in FIG. 7.

As noted above with respect to FIG. 2, the display 48 includes the text indicator 54, which may provide status indications, pricing information, information related to energy usage, and the like. The display 48 also includes the arrow indicator 56, which is configured to provide a visual indication as to the location of taps on the enclosure 100 of the meter 20, and the number indicator 58, which is configured to provide a visual indication of the number of taps in the same location in succession. In the illustrated embodiment, the display 48 also includes a relay indicator 160, which is configured to indicate whether the relay 66 is open (i.e., service is off) or closed (i.e., service is on), and a scroll indicator 162, which is configured to indicate the number of the particular parameter being viewed. For example, in the illustrated embodiment, the scroll indicator 162 is displaying “001,” indicating that the screen is displaying the first viewable parameter. Accordingly, the second viewable parameter may be denoted as “002,” and so on. Alternatively, the scroll indicator 162 may display the number of the viewable parameter, and the total number of viewable parameters, such as via an indication of “001/005,” which may indicate that the first viewable parameter is being displayed out of five possible parameters available for display.

The text indicator 54, in FIG. 7, is displaying a kWh meter value “0079282 kWh,” which represents 79,282 kilowatt hours of energy consumed by the consumer. In a parameter scrolling display mode, the user is able to view various parameters of the meter 20, such as voltage. For example, the user may tap on the bottom 106 of the meter 20, which is shown in the display as an illuminated down arrow 166 and the number indicator displaying “1.” In this situation, the scroll indicator 162 may change to “002,” and the text indicator may display, by way of a non-limiting example, a supply voltage such as “124.018 V,” indicating 124.018 volts of supply on a phase. The user may tap the top 104 of the meter 20, in which case the display 48 would return to displaying “0079282 kWh” on the text indicator 54 and “001” on the scroll indicator 162. An up arrow 168 of the four-way arrow indicator 56 would also become illuminated, with the number indicator 58 remaining at “1.” Likewise, a left arrow 170 will illuminate with a tap on the left 110, a right arrow 172 will illuminate with a tap on the right 108, and a central portion 174 will illuminate with a tap on the front 112. Certain of the arrows may also illuminate when other locations are tapped. For example, the right arrow 172 and the top arrow 168 may illuminate with a tap on the top right 116.

A user may also place the meter 20 into an edit mode, such as by tapping the left 110 and the right 108 of the meter 20 substantially simultaneously. In such a case, the left and right arrows 170, 172 may illuminate. In the edit mode, the text 54 may blink. For example, the text 54 may be displayed in bright-dim sequences, on-off sequences, and the like, indicating that the text 54 is available to edit. To begin editing the text 54, the user may select a first text 176 by tapping on the left 110 of the meter 20. The first text 176 may blink at a different rate than the rest of the text 54 to indicate that it is selected for editing. The user may increment a value of the first text 176 by tapping on the top 104 or bottom 106 of the meter 20. By tapping sequentially on the top 104 or bottom 106, the value may increment from “0” to “9.” For example, in embodiments where the first text 176 is “0” and the user taps the top 104 three times, the first text 176 will display “3.” The value of the text 54, in certain embodiments, may be incremented between numerical, alphabetical, and symbolic characters.

To select a subsequent text, such as a second text 178, the user may tap the left 110 of the meter 20. The process described above may be repeated as desired until all values shown in the text 54 are in accordance with a desired input. Further, it should be noted that any of the places of the text 54 may be changed. For example, in an embodiment where the text 54 displays “0000000,” it may be possible to edit the text 54 to display “0040000” by tapping on the left 110 of the meter 20 four times when in edit mode, and tapping the top 104 four times. The text 54 may be confirmed by tapping the front 112 of the meter 20, or through a combination of taps.

As noted above, the tap interface-enabled energy meter 20 may also be used to restore power to a residence or a commercial site. For example, in situations where the power service has been cut to a customer, the customer may request for the service to be restored. The utility 12 may issue a command to the meter 20 over the AMI network to set the meter 20 into an ARMED mode, in which the text 54 displays “ARMED,” ‘00ARMED,” or a similar indication. The scroll indicator 162 may be used to indicate a particular entry required by the meter 20 via taps. For example, the scroll indicator 162 may display “0F2” for two front taps, “0B4” for four bottom taps, and so on. The meter 20 may call for only one sequence, or multiple sequences to be performed by the user. The relay indicator 160 may display “Open” to indicate that the relay 66 is open and that power is not enabled.

In embodiments where the scroll indicator displays “0F2” and the user taps on the front 112 twice, the central portion 166 illuminates and the number indicator increments to “2.” After the user enters the pre-defined sequence, the text 54, the arrows 56, or any portion of the display 48 may provide an indication, such as a series of flashes, a prolonged illumination, or the like, while the relay 66 is closed and power is restored. After the relay 66 is closed and power is restored, the relay indicator 160 may change to “Closed” and the text 54 may return to a default display parameter, such as real-time use, overall consumption, or another parameter.

It should be noted that the situations described above for the display 48 are examples only, and are not intended to limit the manner in which indications are provided, the parameters that are displayed and editable, and the manner in which the user is able to interact with the meter 20. Rather, any method by which the user is able to interact with the meter 20 via the accelerometer 50 is presently contemplated. Thus, the tap interface-enabled energy meters 20 in accordance with the present disclosure may include analog displays, digital displays, no display, audio interfaces, remote communication interfaces (e.g., via a smart phone, computer, PDA, remote control), and so on.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A utility meter, comprising:
metering circuitry configured to monitor consumption of a utility;
a processor configured to control the metering circuitry;
an enclosure disposed over at least a portion of the metering circuitry and the processor; and
an accelerometer communicatively coupled to the processor, wherein the accelerometer is configured to enable user interactions with the energy meter via one or more taps on the enclosure.

2. The energy meter of claim 1, wherein the accelerometer is coupled directly to the processor, and the processor is configured to read information or data stored in one or more regions of the accelerometer, or the accelerometer is configured to provide digital data to the processor, or a combination thereof.

3. The energy meter of claim 1, wherein the processor comprises an input/output connection, and the accelerometer is coupled to the input/output connection to enable communication between the processor and the accelerometer.

4. The energy meter of claim 1, wherein the accelerometer is configured to provide one or more indications to the processor relating to a location of one or more taps on the enclosure, a magnitude of a force generated by taps on the enclosure, a direction of taps on the enclosure, a number of taps on the enclosure, vibrations of the utility meter as a result of weather, seismic, or tampering activity, or any combination thereof

5. The energy meter of claim 1, comprising a digital display configured to provide user-viewable indications corresponding to a plurality of operational modes of the energy meter, wherein the accelerometer enables a user to navigate through a list of the plurality of operational modes on the digital display.

6. The energy meter of claim 5, wherein the accelerometer is configured to enable the user to select one or more of the plurality of operational modes, and the plurality of operational modes comprises a demand reading state, an idle state, a response state, or any combination thereof

7. The energy meter of claim 6, wherein the digital display is configured to display information related to the utility consumption when in the demand reading state.

8. The energy meter of claim 6, wherein the digital display is configured to display a list of selectable display parameters in response to one or more taps by the user when in the idle state.

9. The energy meter of claim 6, wherein the digital display is configured to prompt the user for one or more predetermined tap sequences when in the response state.

10. The energy meter of claim 1, comprising a communications device communicatively coupling the accelerometer to the processor.

11. The energy meter of claim 10, wherein the communications device is configured to provide information relating to a status of the accelerometer to the processor.

12. The energy meter of claim 11, wherein the communications device comprises an additional processor configured to interpret the tap sequences on the enclosure and provide instructions to the processor to control elements of the metering circuitry based on the tap sequences.

13. The energy meter of claim 1, comprising a communications device configured to enable remote communication between the utility meter and a utility provider, wherein the accelerometer enables communication with the utility provider using the one or more taps on the enclosure, and wherein the utility meter is capable of communicating tamper, seismic, or weather-related notifications, or any combination thereof, to the utility provider as a result of vibrations detected by the accelerometer, the vibrations being indicative of tampering, seismic activity, or weather activity, or any combination thereof

14. An energy meter system, comprising:
user interface circuitry, comprising:
an accelerometer circuit configured to measure acceleration; and
a communications device coupled to the accelerometer and having a first interface configured to communicatively couple the user interface circuitry with a second interface of an energy meter, the energy meter having metering circuitry configured to monitor energy consumption;
wherein the user interface circuitry is configured to enable user interactions with the energy meter using measured acceleration resulting from one or more taps by a user on an enclosure of the energy meter.

15. The energy meter system of claim 14, wherein the communications device comprises a first processor configured to process signals generated by the accelerometer in response to the measured acceleration to determine a direction of the one or more taps, a magnitude of the one or more taps, a frequency of the one or more taps, or any combination thereof

16. The energy meter system of claim 15, wherein the accelerometer and the communications device are a part of a single circuit board, the communications device is configured to communicate with a second processor of the energy meter, the second processor is configured to control at least a portion of the metering circuitry, and the communications device is configured to provide instructions to the second processor to control elements of the metering circuitry based on the direction of the one or more taps, the magnitude of the one or more taps, the frequency of the one or more taps, or any combination thereof

17. The energy meter of claim 16, wherein the instructions comprise update instructions for a digital display of the energy meter, the update instructions being configured to enable the digital display to provide user-visible indications relating to acceleration measured by the accelerometer.

18. A method of operation of an energy meter, comprising:
monitoring energy consumption of a load using metering circuitry of the energy meter;
controlling an operational parameter of the metering circuitry using a processor;
measuring acceleration resulting from one or more taps on an enclosure of the energy meter using an accelerometer; and
adjusting the operational parameter based on the measured acceleration.

19. The method of claim 18, comprising:
interpreting the measured acceleration to determine a direction, a location, a magnitude, or any combination thereof, of each of the one or more taps to generate a set of instructions using an additional processor of a communications device directly coupled to the accelerometer;
communicating the set of instructions to the processor using the communications device; and
executing the set of instructions to adjust the operational parameter using the processsor.

20. The method of claim 18, comprising:
sampling data stored on the accelerometer to determine a direction, a location, a magnitude, or any combination thereof, of each tap of the one or more taps to interpret the tap sequence using the processor; and
executing a set of instructions to update the operational parameter based on the interpreted one or more taps using the processor.
